(19) United States
(12) Patent Application Publication
(10) Pub. No.: US 2026/0248004 A1
(43) Pub. Date: Aug. 20, 2026

(54) PACKAGE SUBSTRATE AND FABRICATING METHOD THEREOF

(71) Applicant: AaltoSemi Inc., Nanjing City (CN)

(72) Inventors: Andrew C. CHANG, Nanjing City (CN); Min-Yao CHEN, Nanjing City (CN); Sung-Kun LIN, Nanjing City (CN); Yin-Ju CHEN, Nanjing City (CN)

(73) Assignee: AaltoSemi Inc., Nanjing City (CN)

(21) Appl. No.: 19/537,825

(22) Filed: Feb. 12, 2026

(30) Foreign Application Priority Data
Feb. 17, 2025 (CN) 202510169493.X

(51) Int. Cl. H10W 70/652; H10W 70/05; H10W 70/63

(52) U.S. Cl. CPC H10W 70/6525; H10W 70/095; H10W 70/63

(57) ABSTRACT

A package substrate is provided, in which a circuit structure is formed on a core layer having a plurality of conductive pillars and wiring layers, and a support structure is formed within the core layer and within the circuit structure in a peripheral region of the core layer. Accordingly, the support structure can effectively suppress delamination of the circuit structure.

### CROSS-REFERENCE TO RELATED APPLICATION

This application claims the benefit of priority of China Patent Application No. 202510169493.X, filed on Feb. 17, 2025, the entire contents of which are incorporated herein by reference.

### BACKGROUND

### 1. Technical Field

The present disclosure relates to semiconductor packaging technology, and more particularly, to a package substrate and a fabricating method thereof that can enhance reliability.

### 2. Description of Related Art

With the evolution of semiconductor packaging technology, semiconductor devices have been developed with various packaging types. In such semiconductor devices, a semiconductor chip is primarily disposed on a package substrate, electrically connected to the package substrate, and then encapsulated with a packaging colloid to cover the semiconductor chip.

FIG. 1A to FIG. 1C are schematic cross-sectional views illustrating a method of fabricating a conventional package substrate 1.

As shown in FIG. 1A, a plurality of through holes 100 are formed in a core layer 10.

As shown in FIG. 1B, wiring layers 12 are respectively formed on upper and lower sides of the core layer 10 by a patterning process, and a plurality of conductive pillars 11 are formed in the through holes 100 and electrically connected to the wiring layers 12.

As shown in FIG. 1C, circuit structures 14 are respectively formed on the upper and lower sides of the core layer 10, and metal sheets 15 are formed at edges of the circuit structures 14. Each of the circuit structures 14 includes at least one dielectric layer 140, at least one circuit layer 141 formed on the dielectric layer 140, and a plurality of conductive blind vias 142 formed in the dielectric layer 140 and electrically connected to the circuit layer 141 and the wiring layer 12.

In subsequent processes, a solder resist layer, such as green solder mask (not shown), may be formed on each of the circuit structures 14.

However, in the method of fabricating the conventional package substrate 1, the metal sheet 15 is too thin. During the process of fabricating the entire board to meet specifications, excessive stress occurs between the dielectric layers 140, thereby making it difficult to suppress delamination between the dielectric layers 140. This results in moisture penetration, which damages electrical functionality or degrades reliability.

On the other hand, the bonding strength between the dielectric layer 140 and the core layer 10 is also poor, making delamination likely to occur under high temperatures during the fabricating process. In addition, due to the insufficient thickness of the metal sheet 15, delamination cannot be effectively suppressed, as shown at an edge portion C in FIG. 1C′. This leads to moisture penetration, which damages electrical functionality or reduces reliability.

Therefore, how to overcome the various shortcomings of the above-mentioned prior art has become an urgent issue to be solved at present.

### SUMMARY

In view of the various shortcomings of the aforementioned prior art, the present disclosure provides a package substrate, which comprises: a core layer being defined with a wiring region and a peripheral region surrounding the wiring region; a plurality of conductive pillars formed within the core layer in the wiring region and connecting opposite sides of the core layer; wiring layers formed on the opposite sides of the core layer and electrically connected to the plurality of conductive pillars; a circuit structure formed on at least one side of the core layer in the wiring region and the peripheral region and electrically connected to the wiring layers; and a support structure formed within the core layer and within the circuit structure in the peripheral region and electrically disconnected from the circuit structure. For example, the support structure (e.g., support pillar and/or support blocks) may be configured to be electrically disconnected from the wiring layers and/or the circuit structure.

The present disclosure further provides a method of fabricating a package substrate, and the method comprises: providing a core layer being defined with a wiring region and a peripheral region surrounding the wiring region; forming a plurality of conductive pillars within the core layer in the wiring region, and forming wiring layers on opposite sides of the core layer, wherein the plurality of conductive pillars connect the opposite sides of the core layer, and the wiring layers are electrically connected to the plurality of conductive pillars; forming a circuit structure on at least one side of the core layer in the wiring region and the peripheral region, wherein the circuit structure is electrically connected to the wiring layers; and forming a support structure within the core layer and within the circuit structure, wherein the support structure is arranged corresponding to the peripheral region.

In a specific aspect of the aforementioned package substrate and method, the circuit structure is formed on each of the opposite sides of the core layer, such that the package substrate is symmetrical.

In a specific aspect of the aforementioned package substrate and method, the circuit structure is formed only on one side of the core layer, such that the package substrate is asymmetrical.

In a specific aspect of the aforementioned package substrate and method, the support structure is not electrically connected to the circuit structure.

In a specific aspect of the aforementioned package substrate and method, the support structure includes at least one support pillar formed within the core layer and at least one support block formed within the circuit structure. For example, the support block is connected to the support pillar such that the support structure is of stacked type. Alternatively, the support block is not connected to the support pillar such that the support structure is of a discontinuous type. Further, the support block may be rivet-shaped, grid-shaped, or frame-shaped.

In a specific aspect of the aforementioned package substrate and method, the support structure includes a plurality of the support blocks, and the support structure further includes at least one connecting pad used to stack and join adjacent upper and lower ones of the plurality of support blocks.

In a specific aspect of the aforementioned package substrate and method, when the support structure is of stacked type, the connecting pad can further be formed between the support block and the support pillar to connect the support block and the support pillar.

In a specific aspect of the aforementioned package substrate and method, the core layer is made of an organic material, glass, ceramic, silicon carbide, AlO₂, or a composite material having a modulus of about 50 GPa to about 100 GPa.

As can be seen from the above, in the package substrate and fabricating method thereof of the present disclosure, by forming the support structure within the core layer and within the circuit structure in the peripheral region, the adhesion between the dielectric layers and between the dielectric layer and the core layer is enhanced. Therefore, compared to the prior art, when delamination occurs between respective dielectric layers (or between the dielectric layer and the core layer) under high temperatures during the fabricating process, the support structure (especially the support block) can effectively suppress delamination, thereby preventing moisture penetration that could damage electrical functionality or compromise reliability.

### BRIEF DESCRIPTION OF THE DRAWINGS

FIG. 1A to FIG. 1C are schematic cross-sectional views illustrating a method of fabricating a conventional package substrate.

FIG. 1C′ is a schematic partially enlarged cross-sectional view of FIG. 1C.

FIG. 2A to FIG. 2C are schematic cross-sectional views illustrating a method of fabricating a package substrate according to the present disclosure.

FIG. 3A and FIG. 3B are schematic top views showing different specifications of package substrates according to the present disclosure.

FIG. 4A to FIG. 4C are schematic cross-sectional views showing other different embodiments of FIG. 2C.

FIG. 5A and FIG. 5B are schematic top views showing other different embodiments of FIG. 3A and FIG. 3B.

FIG. 6A and FIG. 6B are schematic top views showing other different embodiments of FIG. 5A and FIG. 5B.

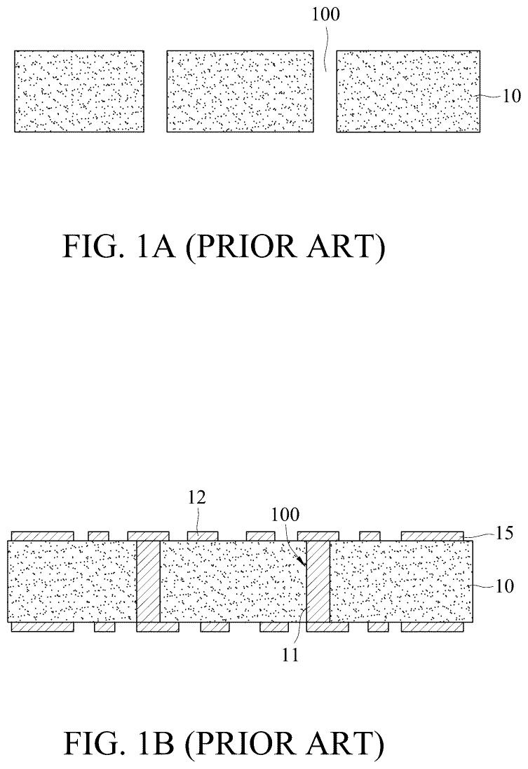

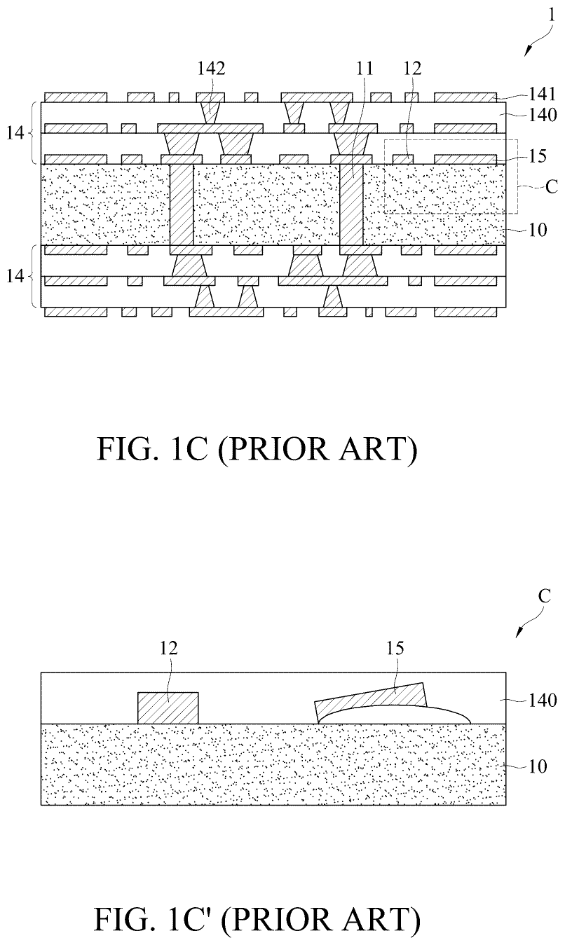

### DETAILED DESCRIPTION

The following describes the implementation of the present disclosure with examples. Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable purposes should still be deemed as falling within the scope defined by the technical content disclosed in the present specification. Meanwhile, terms such as “on,” “first,” “second,” “a,” “one,” and the like are merely for clear explanation rather than limiting the practicable scope of the present disclosure, and thus, alterations or adjustments of the relative relationships thereof without essentially altering the technical content should still be considered in the practicable scope of the present disclosure.

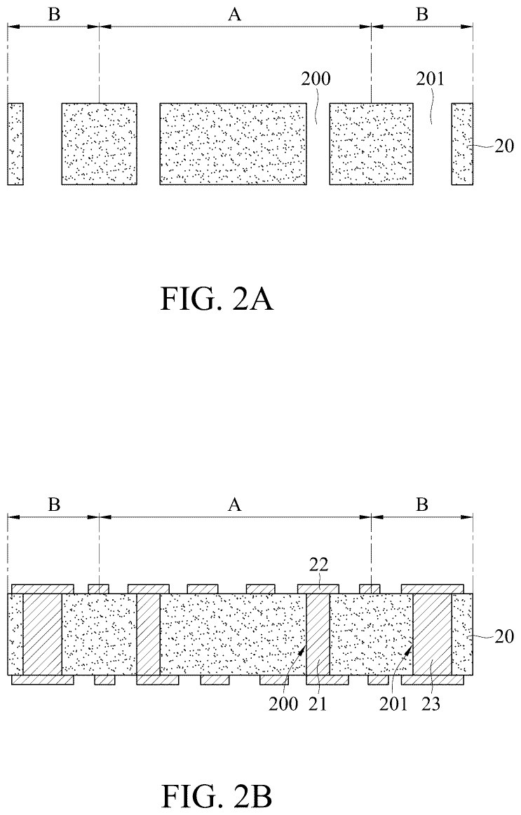

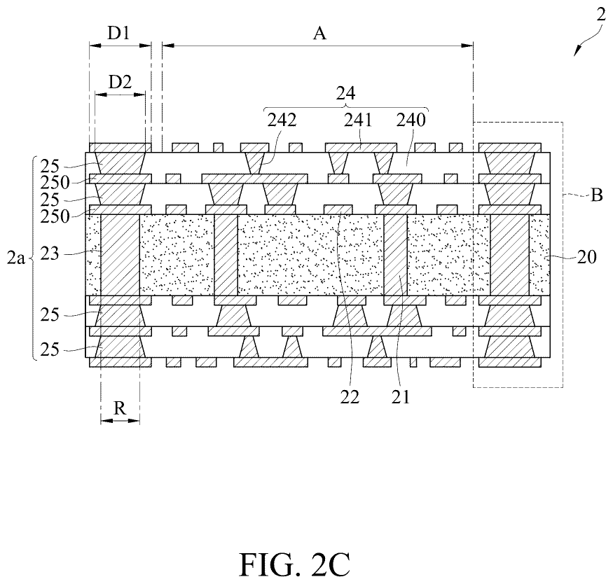

FIG. 2A to FIG. 2C are schematic cross-sectional views illustrating a method of fabricating a package substrate 2 according to the present disclosure.

As shown in FIG. 2A, a core layer 20 is provided. The core layer 20 is defined with a wiring region A and a peripheral region B surrounding the wiring region A. At least one through hole 200 is formed in the wiring region A of the core layer 20 and at least one through groove 201 is formed in the peripheral region B of the core layer 20 by laser, drilling (e.g., mechanical drilling), or other methods.

In an embodiment, the core layer 20 may be made of an organic material, glass, ceramic, silicon carbide (SiC), AlO₂, or a high-rigidity composite material with a modulus of about 50 GPa to about 100 GPa.

As shown in FIG. 2B, wiring layers 22 are respectively formed on opposite sides of the core layer 20 by electroplating and patterning processes. A conductive pillar 21 is formed in each of the through holes 200 and is electrically connected to the wiring layers 22. A support pillar 23 is formed in each of the through grooves 201 and is not electrically connected to the wiring layers 22.

In an embodiment, the wiring layers 22, the conductive pillars 21, and the support pillars 23 may be formed by electroplating metal (such as copper) or other methods.

Moreover, the plurality of conductive pillars 21 are solid metal pillars, such as copper pillars. Alternatively, in other embodiments, the plurality of conductive pillars 21 may be hollow copper pillars, and the hollows can be filled with a plugging material (not shown) such as an insulating material or a conductive material, but not limited thereto.

As shown in FIG. 2C, circuit structures 24 are respectively formed on opposite sides of the core layer 20 and are electrically connected to the wiring layers 22, and support blocks 25 are formed on opposite sides of the core layer 20 and are stacked on and connected to each of the support pillars 23, thereby forming a symmetrical package substrate 2. At least one support structure 2a is formed in the peripheral region B of the package substrate 2. In subsequent processes, a solder resist layer, such as green solder mask (not shown), may be formed on each of the circuit structures 24.

Each of the circuit structures 24 includes at least one dielectric layer 240, at least one circuit layer 241 formed on the dielectric layer 240, and a plurality of conductive blind vias 242 formed in the dielectric layer 240 and electrically connected to the circuit layer 241 and the wiring layer 22. Accordingly, when the circuit layers 241 are formed, connecting pads 250 connecting the adjacent upper and lower support blocks 25 and connecting pads 250 connecting the support pillars 23 and the support blocks 25 may be simultaneously and/or correspondingly formed (e.g., connecting pads 250 may be formed at interfaces between adjacent support blocks 25 and/or between the support pillars 23 and the support blocks 25).

In an embodiment, the dielectric layer 240 may be made of bismaleimide triazine (BT), prepreg (PP), Ajinomoto Build-up Film (ABF), polybenzoxazole (PBO), polyimide (PI), or other dielectric materials.

The support block 25 is bonded to the dielectric layer 240 and is not electrically connected to the circuit layer 241 and the wiring layer 22.

In an embodiment, the fabrication of the support block 25 is the same as the fabrication of the circuit layer 241 and the conductive blind via 242. For example, the support block 25 is rivet-shaped, and a diameter D1 of the connecting pad 250 serving as a cap is greater than a diameter D2 of the support block 25 serving as a nail and a diameter R of the support pillar 23. It should be understood that the support structure 2a may be made of any material suitable for bonding the core layer 20 and the dielectric layer 240.

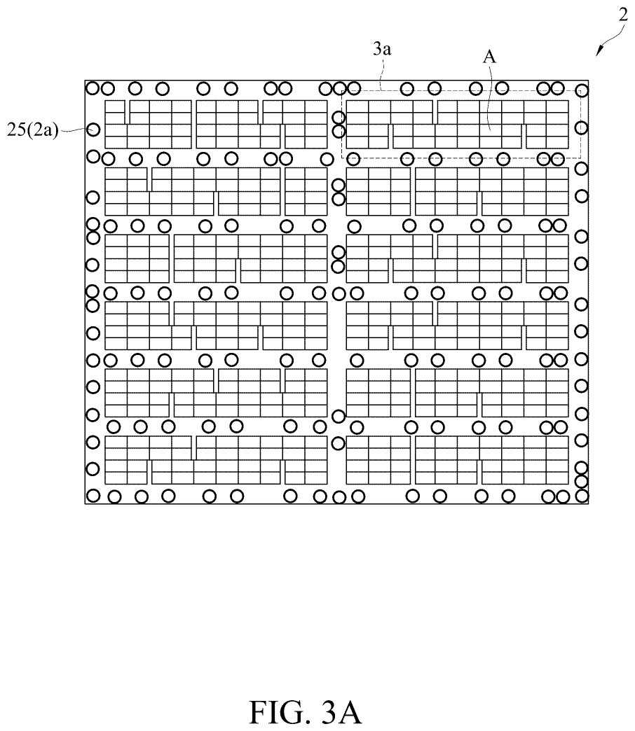

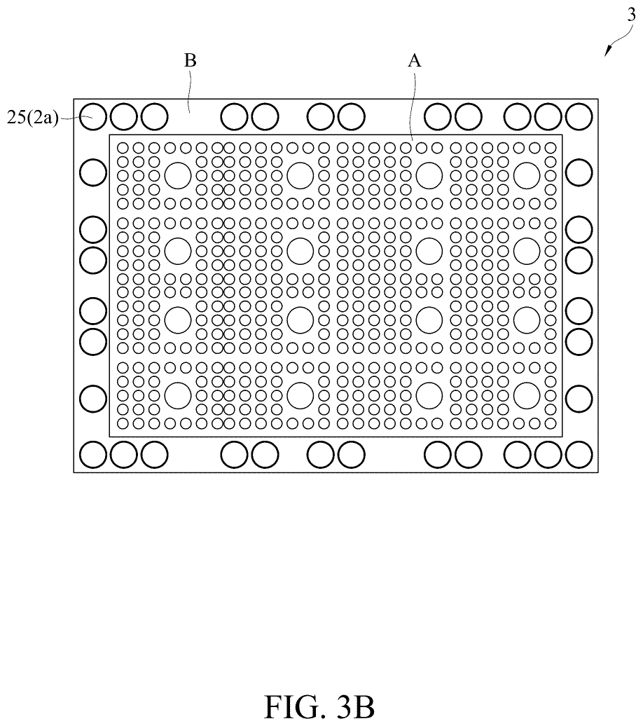

Moreover, an end surface of the support structure 2a (or an outer end of the support block 25) is in the shape of a circular pad, as shown in FIG. 3A or FIG. 3B, and a plurality of support structures 2a are arranged around the peripheral region B of the package substrate 2. For example, the package substrate 2 is in a full-panel specification including a plurality of strips 3a, as shown in FIG. 3A, such that the plurality of support structures 2a surround the wiring region A of each of the strips 3a. Alternatively, as shown in FIG. 3B, the package substrate 3 is in a single-material specification (single-substrate specification). As shown in FIG. 3B, the plurality of support structures 2a surround the wiring region A of the package substrate 3.

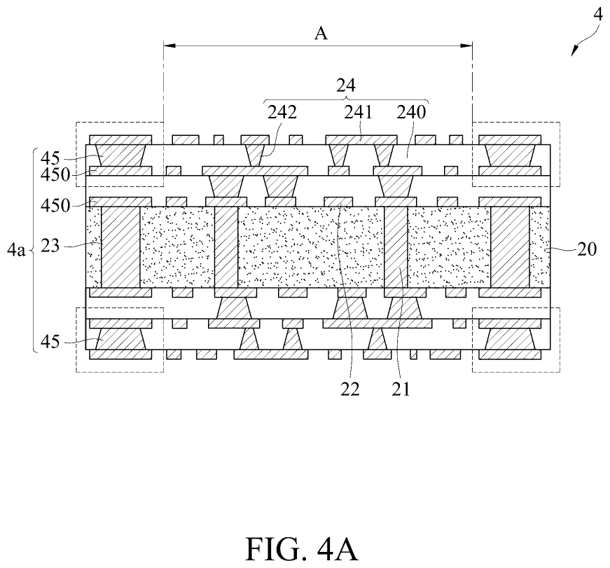

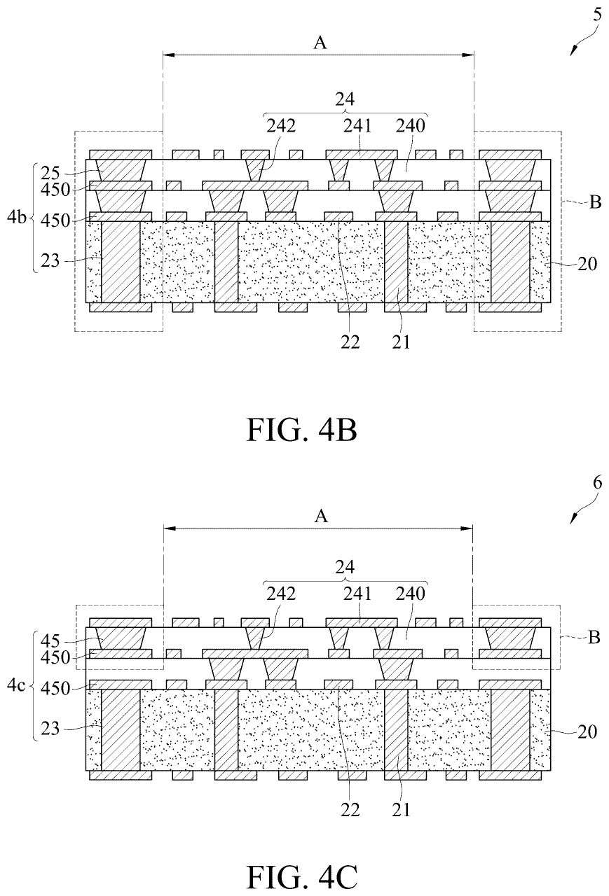

Furthermore, the support structure 2a has various aspects and can be designed according to requirements. For example, in the symmetrical package substrate 4 shown in FIG. 4A, the support block 45 is not connected to the support pillar 23, thereby resulting in a discontinuous support structure 4a. However, connecting pads 450 may be formed at ends of the support pillar 23 and at ends of the support block 45 as needed to enhance interlayer adhesion. Alternatively, the support structure 4b, 4c can be modified according to the type of the package substrate 5, 6, as shown in FIG. 4B or FIG. 4C. The circuit structure 24 and the support block 25, 45 are formed only on one side of the core layer 20 to form an asymmetrical package substrate 5, 6, thereby resulting in an asymmetrical stacked support structure 4b or an asymmetrical discontinuous support structure 4c.

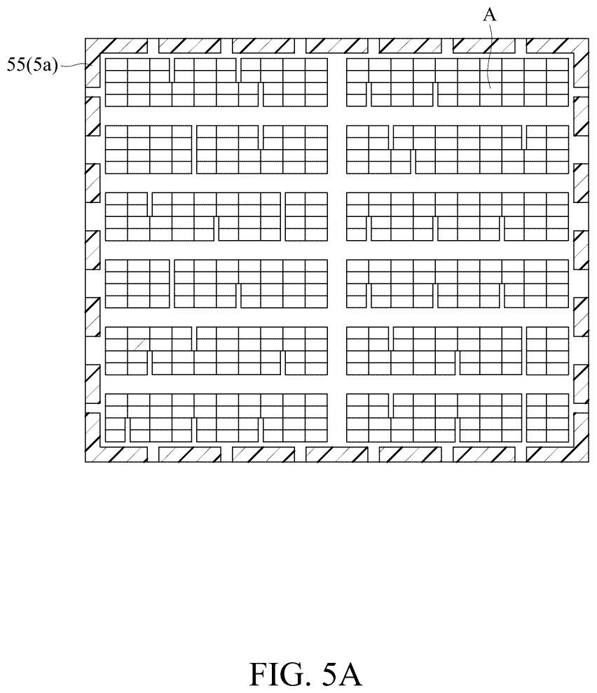

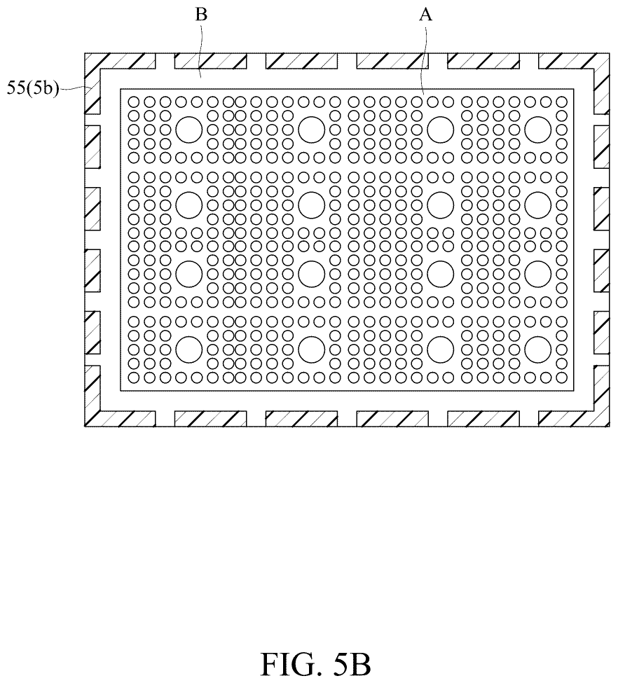

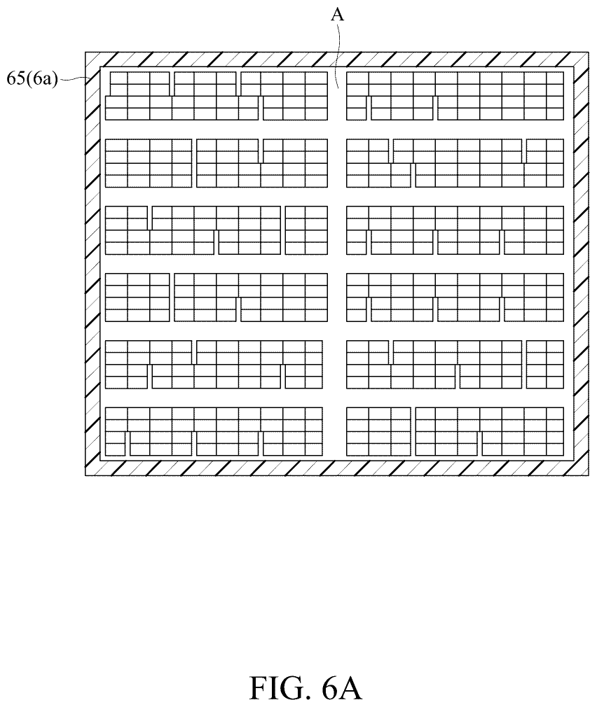

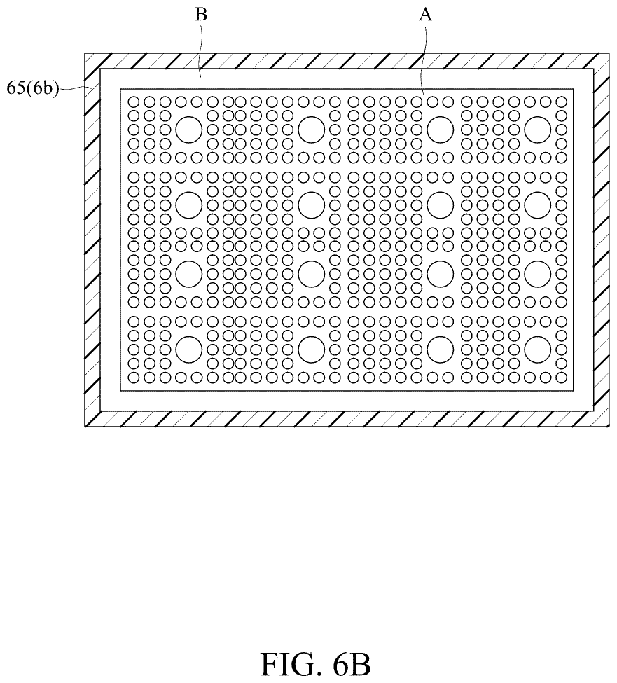

In addition, the occupied area of the support structure 2a can also be designed according to requirements. For example, in the full-panel specification shown in FIG. 5A or in the single-material specification (single-substrate specification) shown in FIG. 5B, the support block 55 can be hedge-shaped (e.g., grid-shaped), and its end surface (or an outer end of the support block 55) is rectangular. Alternatively, in the full-panel specification shown in FIG. 6A or in the single-material specification (single-substrate specification) shown in FIG. 6B, the support block 65 forms a frame or is frame-shaped, and its end surface (or an outer end of the support block 65) is annular.

It should be understood that in the aspects shown in FIG. 5A, FIG. 5B, FIG. 6A, and FIG. 6B, a connecting pad (not shown) may also be formed between adjacent upper and lower support blocks 55, 65. The connecting pad (not shown) may also be formed between the support block 55, 65 and the support pillar 23. Moreover, whether in the full-panel specification or in the single-material specification (single-substrate specification), the package substrate 2, 3, 4, 5, 6 can be classified into twelve aspects based on the support structure 2a, 4a, 4b, 4c, 5a, 5b, 6a, 6b, as shown in Table 1 below.

TABLE 1
Package Substrate (Full-Panel Specification or Single-Material Specification)
Support Structure

| Stacked type | | | | | | Discontinuous type | | | | | |
|---|---|---|---|---|---|---|---|---|---|---|---|
| Symmetrical | | | Asymmetrical | | | Symmetrical | | | Asymmetrical | | |
| Rivet | Grid | Frame | Rivet | Grid | Frame | Rivet | Grid | Frame | Rivet | Grid | Frame |
| shape | shape | shape | shape | shape | shape | shape | shape | shape | shape | shape | shape |

Therefore, in the package substrate 2, 3, 4, 5, 6 of the present disclosure, the support structure 2a, 4a, 4b, 4c, 5a, 5b, 6a, 6b formed in the peripheral region B, with support block 25, 45, 55, 65 in rivet-shaped, grid-shaped, or frame-shaped configuration, can enhance adhesion between the dielectric layer 240 and the core layer 20 and also enhance the adhesion between the dielectric layers 240. Therefore, compared to the prior art, when delamination occurs between respective dielectric layers 240 (or between the dielectric layer 240 and the core layer 20) under high temperatures during the fabricating process, the support structure 2a, 4a, 4b, 4c, 5a, 5b, 6a, 6b (especially the support block 25, 45, 55, 65) can effectively suppress delamination, especially at the edge of the package substrate 2, 3, 4, 5, 6, thereby preventing moisture penetration that could damage electrical functionality or compromise reliability.

Moreover, the stacked support structure 2a, 4b can simultaneously prevent/suppress delamination between the dielectric layer 240 and the core layer 20, as well as delamination between the dielectric layers 240. The discontinuous support structure 4a, 4c is used to prevent/suppress delamination between the dielectric layers 240.

Furthermore, regardless of whether the package substrate 2, 3, 4, 5, 6 is in full-panel specification (strip 3a specification) or single-material specification (single-substrate specification), the support structure 2a, 4a, 4b, 4c, 5a, 5b, 6a, 6b can be easily arranged in the peripheral region B. This allows the package substrate 2, 3, 4, 5, 6 to effectively reduce the occurrence of delamination during both fabricating and reliability testing stages, based on the distribution area or quantity of the support structure 2a, 4a, 4b, 4c, 5a, 5b, 6a, 6b. Therefore, the package substrate 2, 3, 4, 5, 6 can be designed to configure the support structure 2a, 4a, 4b, 4c, 5a, 5b, 6a, 6b in regions with high delamination risk according to requirements to prevent delamination issues.

The present disclosure also provides a package substrate 2, 3, 4, 5, 6. The package substrate 2, 3, 4, 5, 6 comprises: a core layer 20, a plurality of conductive pillars 21, wiring layers 22, at least one circuit structure 24, and at least one support structure 2a, 4a, 4b, 4c, 5a, 5b, 6a, 6b.

The core layer 20 is defined with a wiring region A and a peripheral region B surrounding the wiring region A.

The plurality of conductive pillars 21 are disposed within the core layer 20 in the wiring region A and connect opposite sides of the core layer 20.

The wiring layers 22 are formed on the opposite sides of the core layer 20 and are electrically connected to the plurality of conductive pillars 21.

The circuit structure 24 is disposed on at least one side of the core layer 20 in the wiring region A and the peripheral region B and is electrically connected to the wiring layers 22.

The support structure 2a, 4a, 4b, 4c, 5a, 5b, 6a, 6b is disposed within the core layer 20 and within the circuit structure 24, and is arranged corresponding to the peripheral region B.

In a specific aspect, the circuit structure 24 is formed on each of the opposite sides of the core layer 20, such that the package substrate 2 is symmetrical.

In a specific aspect, the circuit structure 24 is formed only on one side of the core layer 20, such that the package substrate 4, 6 is asymmetrical.

In a specific aspect, the support structure 2a, 4a, 4b, 4c, 5a, 5b, 6a, 6b is not electrically connected to the circuit structure 24.

In a specific aspect, the support structure 2a, 4a, 4b, 4c, 5a, 5b, 6a, 6b includes at least one support pillar 23 formed within the core layer 20 and at least one support block 25, 45, 55, 65 formed within the circuit structure 24. For example, the support block 25 is connected to the support pillar 23, such that the support structure 2a, 4b is of stacked type. Alternatively, the support block 45 is not connected to the support pillar 23, such that the support structure 4a, 4c is of discontinuous type.

In a specific aspect, the support structure 2a, 4a, 4b, 4c, 5a, 5b, 6a, 6b may include a plurality of support blocks 25, 45, 55, 65, and the support structure 2a, 4a, 4b, 4c, 5a, 5b, 6a, 6b further includes at least one connecting pad 250, 450 for stacking and joining adjacent upper and lower support blocks 25, 45, 55, 65.

In a specific aspect, the connecting pad 250, 450 may further be formed between the support block 25, 45, 55, 65 and the support pillar 23 to connect the support block 25, 45, 55, 65 and the support pillar 23.

In an embodiment, the support block 25, 45 is rivet-shaped. Alternatively, the support block 55 is grid-shaped. Even more specifically, the support block 65 is a frame or frame-shaped.

In summary, in the package substrate and fabricating method thereof of the present disclosure, by forming the support structure within the core layer and within the circuit structure in the peripheral region, the adhesion between the dielectric layers and between the dielectric layer and the core layer is enhanced. Therefore, compared to the prior art, when delamination occurs between respective dielectric layers (or between the dielectric layer and the core layer) under high temperatures during the fabricating process, the support structure (especially the support block) can effectively suppress delamination, thereby preventing moisture penetration that could damage electrical functionality or compromise reliability.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

1. A package substrate, comprising:
a core layer defined with a wiring region and a peripheral region surrounding the wiring region;
a plurality of conductive pillars formed within the core layer in the wiring region and connecting opposite sides of the core layer;
wiring layers formed on the opposite sides of the core layer and electrically connected to the plurality of conductive pillars;
a circuit structure formed on at least one of the opposite sides of the core layer in the wiring region and the peripheral region and electrically connected to the wiring layers; and
a support structure formed within the core layer and within the circuit structure in the peripheral region and including at least one support pillar formed within the core layer and at least one support block formed within the circuit structure, the support pillar electrically disconnected from the wiring layers, and the support block electrically disconnected from the circuit structure and the wiring layers.

2. The package substrate of claim 1, wherein the at least one support block is connected to the at least one support pillar such that the support structure is of stacked type, or the at least one support block is not connected to the at least one support pillar.

3. The package substrate of claim 1, wherein the support structure includes a plurality of the support blocks, the support structure further includes connecting pads, the connecting pads are used to stack and join adjacent upper and lower ones of the plurality of support blocks, and when the support structure is of a stacked type, the connecting pads connect the plurality of support blocks and the at least one support pillar.

4. The package substrate of claim 1, wherein the at least one support block is rivet-shaped, grid-shaped, or frame-shaped.

5. The package substrate of claim 1, wherein the core layer is made of an organic material, glass, ceramic, silicon carbide, AlO₂, or a composite material having a modulus of 50 GPa to 100 GPa.

6. A method of fabricating a package substrate, the method comprising:
providing a core layer defined with a wiring region and a peripheral region surrounding the wiring region;
forming a plurality of conductive pillars within the core layer in the wiring region, and forming wiring layers on opposite sides of the core layer, wherein the plurality of conductive pillars connect the opposite sides of the core layer, and the wiring layers are electrically connected to the plurality of conductive pillars;
forming a circuit structure on at least one of the opposite sides of the core layer in the wiring region and the peripheral region, wherein the circuit structure is electrically connected to the wiring layers; and
forming a support structure within the core layer and within the circuit structure, wherein the support structure is arranged corresponding to the peripheral region, the support structure includes at least one support pillar formed within the core layer and at least one support block formed within the circuit structure, the support pillar is electrically disconnected from the wiring layers, and the support block is electrically disconnected from the circuit structure and the wiring layers.

7. The method of claim 6, wherein the at least one support block is connected to the at least one support pillar such that the support structure is of stacked type, or the at least one support block is not connected to the at least one support pillar.

8. The method of claim 6, wherein the support structure includes a plurality of the support blocks, the support structure further includes connecting pads, the connecting pads are used to stack and join adjacent upper and lower ones of the plurality of support blocks, and when the support structure is of stacked type, the connecting pads connect the plurality of support blocks and the at least one support pillar.

9. The method of claim 6, wherein the at least one support block is rivet-shaped, grid-shaped, or frame-shaped.

10. The method of claim 6, wherein the core layer is made of an organic material, glass, ceramic, silicon carbide, AlO₂, or a composite material having a modulus of 50 GPa to 100 GPa.
